(19) United States
(12) Patent Application Publication
(10) Pub. No.: US 2026/0333878 A1
(43) Pub. Date: Oct. 22, 2026

(54) SEMICONDUCTOR DEVICE

(71) Applicant: Mitsubishi Electric Corporation, Tokyo (JP)

(72) Inventors: Manami TANAKA, Fukuoka (JP); Hiroyuki NAKAMURA, Fukuoka (JP); Yoshifumi TOMOMATSU, Fukuoka (JP)

(73) Assignee: Mitsubishi Electric Corporation, Tokyo (JP)

(21) Appl. No.: 19/529,221

(22) Filed: Feb. 4, 2026

(30) Foreign Application Priority Data
Apr. 16, 2025 (JP) 2025-067367

(51) Int. Cl. H10D 89/60; H10D 12/00; H10D 30/66; H10D 62/83; H10D 62/832

(52) U.S. Cl. CPC H10D 89/811; H10D 12/481; H10D 30/668; H10D 62/83; H10D 62/8325

(57) ABSTRACT

A semiconductor device includes: a semiconductor switching element including a gate terminal, a main terminal, and a sense terminal that outputs a sense voltage lower than a voltage of the main terminal; and a control circuit that includes a desat terminal electrically connected to the sense terminal without interposition of a diode, and controls a gate voltage of the gate terminal based on the sense voltage. While the semiconductor switching element is short-circuited and the voltage of the main terminal falls and rises, the sense voltage rises without falling.

### BACKGROUND

### Technical Field

The present disclosure relates to a semiconductor device.

### Description of the Background Art

Various techniques have been proposed to protect a semiconductor switching element from an excessive short-circuit current at the time of a short circuit in a semiconductor device such as a power device. For example, International Publication No. WO 2014/115272 discloses that a desat (DESAT) function for monitoring a collector voltage of a semiconductor switching element is provided, and that the semiconductor switching element is protected from a short-circuit current when the collector voltage becomes greater than or equal to a threshold.

However, in order to input a relatively large collector voltage to a desat terminal that is a terminal for a desat function, it is necessary to provide a high-voltage diode for blocking a high voltage between the desat terminal and the collector terminal. As a result, an increase in device cost has been a problem.

### SUMMARY

The present disclosure has been made in view of the above problems, and an object of the present disclosure is to provide a technique capable of reducing device cost.

A semiconductor device according to the present disclosure includes: a semiconductor switching element including a gate terminal, a main terminal that is a collector terminal or a drain terminal, and a sense terminal that outputs a sense voltage lower than a voltage of the main terminal; and a control circuit that includes a desat terminal electrically connected to the sense terminal without interposition of a diode, and controls a gate voltage of the gate terminal based on the sense voltage input to the desat terminal. While the semiconductor switching element is short-circuited and the voltage of the main terminal falls and rises, the sense voltage rises without falling.

It is possible to reduce device cost.

These and other objects, features, aspects and advantages of the present disclosure will become more apparent from the following detailed description of the present disclosure when taken in conjunction with the accompanying drawings.

### BRIEF DESCRIPTION OF THE DRAWINGS

FIG. 1 is a circuit diagram illustrating a configuration of a semiconductor device according to a first preferred embodiment;

FIG. 2 is a cross-sectional view illustrating a configuration of a semiconductor switching element according to the first preferred embodiment;

FIG. 3 is a plan view illustrating a configuration of a gate terminal and a sense terminal according to the first preferred embodiment; and

FIG. 4 is a circuit diagram illustrating a configuration of a semiconductor device according to a second preferred embodiment.

### DESCRIPTION OF THE PREFERRED EMBODIMENTS

Hereinafter, preferred embodiments will be described with reference to the attached drawings. Features described in the following preferred embodiments are examples, and all features are not necessarily essential. In the following description, similar components in a plurality of preferred embodiments are denoted by the same or similar reference numerals, and different components will be mainly described. Furthermore, in the following description, specific positions and directions such as “upper”, “lower”, “left”, “right”, “front”, or “back” may not necessarily coincide with actual positions and directions in practice. The fact that one portion has a higher concentration than another portion may mean, for example, that an average or a peak of the concentration of one portion is higher than an average or a peak of the concentration of another portion. Conversely, the fact that one portion has a lower concentration than another portion may mean, for example, that an average or a peak of the concentration of one portion is lower than an average or a peak of the concentration of another portion. In the following description, a first conductivity type is n-type and a second conductivity type is p-type, but the first conductivity type may be p-type and the second conductivity type may be n-type. General impurities may be used as n-type and p-type impurities.

### First Preferred Embodiment

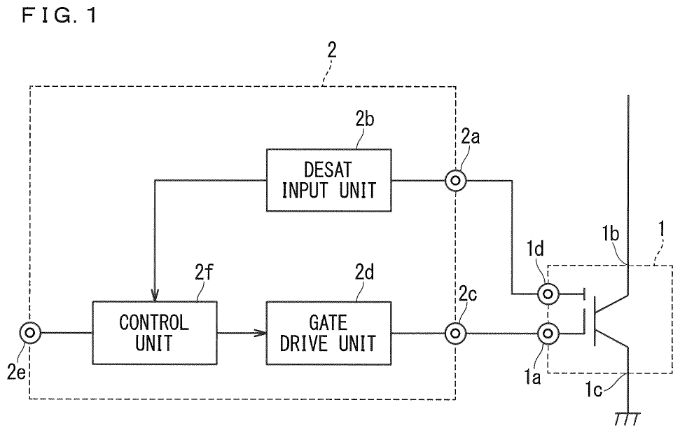

FIG. 1 is a circuit diagram illustrating a configuration of a semiconductor device according to a first preferred embodiment. The semiconductor device according to the first preferred embodiment is, for example, a power device, and includes a semiconductor switching element 1 and a control circuit 2.

### Semiconductor Switching Element 1

The semiconductor switching element 1 includes a gate terminal, a main terminal that is a collector terminal or a drain terminal, an emitter terminal or a source terminal, and a sense terminal. Hereinafter, as illustrated in FIG. 1, an example will be described in which the semiconductor switching element 1 is a carrier stored trench gate bipolar transistor (CSTBT) including a gate terminal 1a, a collector terminal 1b, an emitter terminal 1c, and a sense terminal 1d. However, as described later, the semiconductor switching element 1 is not limited to a cstbt.

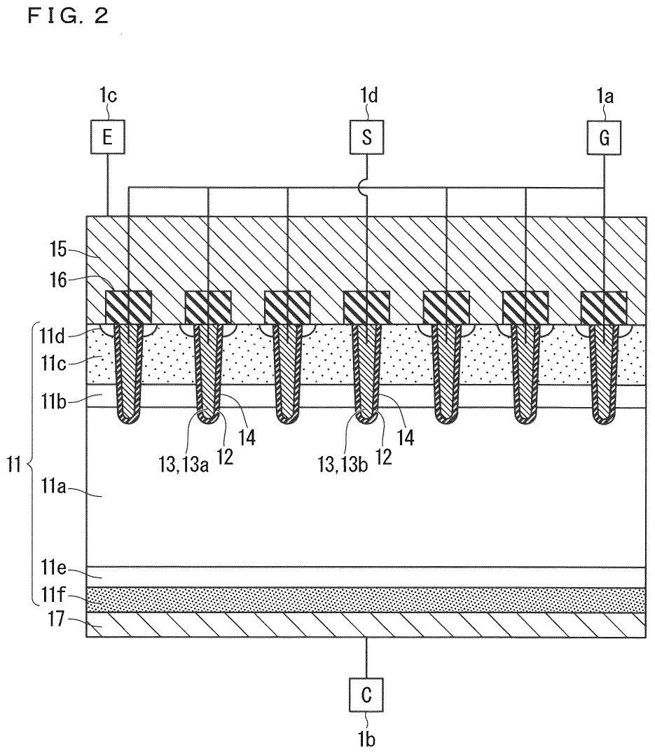

FIG. 2 is a cross-sectional view illustrating the configuration of the semiconductor switching element 1 according to the first preferred embodiment. The semiconductor switching element 1 of FIG. 2 includes not only the gate terminal 1a and the like described above but also a semiconductor layer 11, a plurality of insulating films 12, a plurality of trench electrodes 13, an emitter electrode 15, an interlayer insulating film 16, and a collector electrode 17.

The semiconductor layer 11 may be made of normal silicon (Si), or may be made of a wide band gap semiconductor such as silicon carbide (SiC), gallium nitride (GaN), gallium oxide (Ga₂O₃), or diamond. When the semiconductor layer 11 is formed of a wide band gap semiconductor, it is possible to stably operate the semiconductor switching element 1 at a high temperature and at a high voltage and to increase the switching speed. The semiconductor layer 11 may be formed of a normal semiconductor wafer or an epitaxial growth layer.

The semiconductor layer 11 includes an n-type drift layer 11a, an n-type carrier stored layer (CS layer) 11b, a p-type base layer 11c, an n-type emitter layer 11d, an n-type buffer layer 11e, and a p-type collector layer 11f.

The CS layer 11b is provided on the drift layer 11a, and the n-type impurity concentration of the CS layer 11b is higher than the impurity concentration of the drift layer 11a. The base layer 11c is provided on the CS layer 11b and is provided on an upper side of the drift layer 11a. The emitter layer 11d is selectively provided in an upper portion of the base layer 11c.

The buffer layer 11e is provided under the drift layer 11a, and the n-type impurity concentration of the buffer layer 11e is higher than the impurity concentration of the drift layer 11a. The collector layer 11f is provided under the buffer layer 11e.

The upper surface of the semiconductor layer 11 includes the upper surface of the base layer 11c and the upper surface of the emitter layer 11d, and is provided with a plurality of trenches 14 reaching the drift layer 11a from the upper surface of the semiconductor layer 11. The plurality of trench electrodes 13 are provided on the plurality of trenches 14 via the plurality of insulating films 12, respectively.

The plurality of trench electrodes 13 include a gate electrode 13a electrically connected to the gate terminal 1a and a floating electrode 13b electrically connected to the sense terminal 1d. In the example of FIG. 2, the trench 14 provided with the gate electrode 13a reaches the drift layer 11a from the upper surface of the emitter layer 11d, and the trench 14 provided with the floating electrode 13b reaches the drift layer 11a from the upper surface of the base layer 11c.

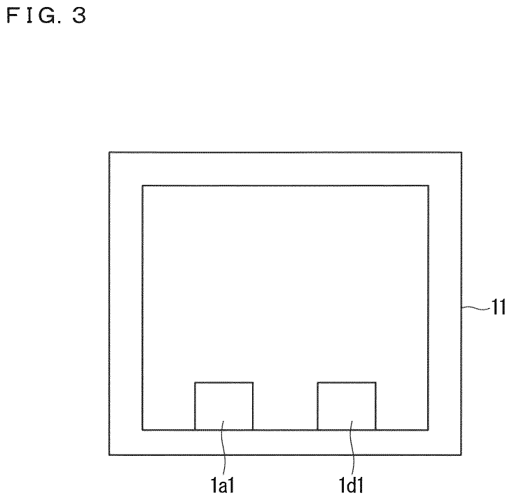

The number of gate electrodes 13a may be one or more, and the number of floating electrodes 13b may be one or more. As illustrated in FIG. 3, the gate terminal 1a may include a gate pad 1a1 for controlling the gate voltage of the gate electrode 13a. The sense terminal 1d may include a voltage sense pad 1d1 that outputs a sense voltage corresponding to the potential of the floating electrode 13b to the outside of the semiconductor switching element 1.

The emitter electrode 15 in FIG. 2 is connected to the base layer 11c and the emitter layer 11d, and is electrically connected to the emitter terminal 1c. The interlayer insulating film 16 insulates between the trench electrode 13 and the emitter electrode 15. The collector electrode 17 is connected to the collector layer 11f and is electrically connected to the collector terminal 1b.

Next, the operation of the semiconductor switching element 1 according to the first preferred embodiment will be described. When the gate voltage of the gate terminal 1a and the gate electrode 13a is a first voltage greater than or equal to a threshold voltage, the semiconductor switching element 1 is turned on, and a channel through which a current can flow between the drift layer 11a and the emitter layer 11d is formed in the base layer 11c. When the gate voltage of the gate terminal 1a and the gate electrode 13a is a second voltage less than the threshold voltage, the semiconductor switching element 1 is turned off, and a current does not substantially flow between the drift layer 11a and the emitter layer 11d.

In the configuration of FIG. 2, the voltage of the floating electrode 13b is a voltage obtained by dividing the voltage between the collector electrode 17 and the emitter electrode 15 by the capacitance between the gate electrode 13a and the emitter electrode 15 and the capacitance between the gate electrode 13a and the collector electrode 17. Therefore, when the voltage between the collector electrode 17 and the emitter electrode 15, that is, the collector voltage of the collector terminal 1b, changes, the voltage of the floating electrode 13b changes, and the sense voltage of the sense terminal 1d electrically connected to the floating electrode 13b also changes. In addition, by dividing the voltage, the sense voltage (e.g., tens of volts) of the sense terminal 1d becomes lower than the collector voltage (e.g., hundreds of volts) of the collector terminal 1b.

When the semiconductor switching element 1 is not short-circuited, the sense voltage tends to change due to a change in the collector voltage of the collector terminal 1b, and the sense voltage substantially corresponds to (substantially tracks) the collector voltage.

However, immediately after a short circuit of the semiconductor switching element 1, the collector voltage is affected by a voltage V=L·di/dt. Here, L is an inductance, i is a collector current of the collector terminal 1b, and t is time. Affected by the voltage V, the collector voltage of the collector terminal 1b temporarily falls due to a change in the collector current i immediately after the short circuit and then rises. As described above, while the collector voltage falls due to the change in the collector current i immediately after the short circuit and then rises, the sense voltage rises without falling due to the change in the collector current immediately after the short circuit.

### Control Circuit 2

The control circuit 2 of FIG. 1 includes a desat terminal 2a, a desat input unit 2b, an output terminal 2c, a gate drive unit 2d, an input terminal 2e, and a control unit 2f. As described below, the control circuit 2 is configured to control the gate voltage of the gate terminal 1a based on the sense voltage of the sense terminal 1d.

The desat terminal 2a is electrically connected to the sense terminal 1d of the semiconductor switching element 1 without interposition of a diode, and the sense voltage output from the sense terminal 1d is input to the desat terminal 2a. In the example of FIG. 1, the desat terminal 2a is electrically connected to the sense terminal 1d via only wiring without interposition of a diode, a capacitor, or a resistor element.

The desat input unit 2b determines whether the sense voltage input to the desat terminal 2a is greater than or equal to a predetermined threshold. The output terminal 2c is electrically connected to the gate terminal 1a of the semiconductor switching element 1. The gate drive unit 2d controls the gate voltage of the gate terminal 1a via the output terminal 2c.

The control unit 2f of the control circuit 2 controls the gate drive unit 2d based on an input signal input to the input terminal 2e and a determination result of the desat input unit 2b, thereby changing the gate voltage to either the first voltage or the second voltage. As a result, the semiconductor switching element 1 is changed to either an ON state or an OFF state.

In the first preferred embodiment, when the desat input unit 2b determines that the gate voltage is the first voltage and the sense voltage is greater than or equal to the predetermined threshold, the control unit 2f of the control circuit 2 controls the gate voltage to the second voltage. That is, when the semiconductor switching element 1 is on and the sense voltage is greater than or equal to the predetermined threshold, the control unit 2f of the control circuit 2 turns off the semiconductor switching element 1, thereby protecting the semiconductor switching element 1. In all other cases, the control unit 2f of the control circuit 2 controls the gate drive unit 2d based on a rectangular input signal input to the input terminal 2e, thereby alternately changing the gate voltage to the first voltage and the second voltage.

### Summary of First Preferred Embodiment

According to the semiconductor device of the first preferred embodiment, the sense voltage of the sense terminal 1d is lower than the collector voltage of the collector terminal 1b. Therefore, the sense terminal 1d of the semiconductor switching element 1 and the desat terminal 2a of the control circuit 2 can be electrically connected without interposition of a diode such as a high-voltage diode, so that device cost can be reduced.

In the first preferred embodiment, while the semiconductor switching element 1 is short-circuited and the collector voltage of the collector terminal 1b falls and rises, the sense voltage rises without falling. A conventional semiconductor device has a problem in that such a semiconductor switching element 1 cannot be quickly protected because the protection is performed based on a collector voltage that does not monotonically rise immediately after a short circuit. In contrast, in the first preferred embodiment, the semiconductor switching element 1 can be quickly protected because the control circuit 2 controls the gate voltage of the gate terminal 1a based on a sense voltage that monotonically rises immediately after a short circuit.

In general, when the threshold voltage of the semiconductor switching element 1 is lowered to increase the energization capability of the semiconductor switching element 1, a power loss can be reduced. However, there is a problem that a short-circuit current due to a short circuit during an ON state of the semiconductor switching element 1 becomes excessive. In contrast, in the first preferred embodiment, when the gate voltage is the first voltage and the sense voltage is greater than or equal to a predetermined threshold, the control circuit 2 controls the gate voltage to the second voltage. That is, when the semiconductor switching element 1 is on and the sense voltage is greater than or equal to the predetermined threshold, the semiconductor switching element 1 is turned off, so that the semiconductor device can be quickly protected from an excessive short-circuit current during an ON state of the semiconductor switching element 1.

In the first preferred embodiment, the semiconductor switching element 1 includes a plurality of trench electrodes 13, and the plurality of trench electrodes 13 includes a gate electrode 13a and a floating electrode 13b. With such a configuration, it is possible to achieve the semiconductor switching element 1 in which the sense voltage of the sense terminal 1d is lower than the collector voltage of the collector terminal 1b.

In the first preferred embodiment, the semiconductor switching element 1 is a CSTBT, that is, an insulated gate bipolar transistor (IGBT) including the CS layer 11b. With such a configuration, by adjusting the n-type impurity concentration of the CS layer 11b, extension of a depletion layer and a potential distribution around the CS layer 11b can be adjusted, and as a result, the sense voltage can be adjusted.

Note that the desat input unit 2b, the gate drive unit 2d, and the control unit 2f of the control circuit 2 may be included in an integrated circuit (IC) in one chip. With such a configuration, the size and cost of the control circuit 2 can be reduced.

### First Modification

In the first preferred embodiment, the semiconductor switching element 1 has been a CSTBT, but is not limited thereto. For example, the semiconductor switching element 1 may be, for example, an IGBT obtained by removal of the CS layer 11b of FIG. 2 from the CSTBT, or may be a reverse conducting insulated gate bipolar transistor (RC-IGBT) in which an IGBT and a diode are provided in the same semiconductor layer. With such a configuration, a sense voltage can be made lower than in the case of a CSTBT, thereby increasing a margin of insulation design of the floating electrode 13b.

The semiconductor switching element 1 may be, for example, a metal-oxide-semiconductor field-effect transistor (MOSFET) obtained by removal of the collector layer 11f in FIG. 2 from the IGBT and containing Si or SiC. In this case, the collector and the emitter of the first preferred embodiment are replaced with a drain and a source, respectively.

### Second Preferred Embodiment

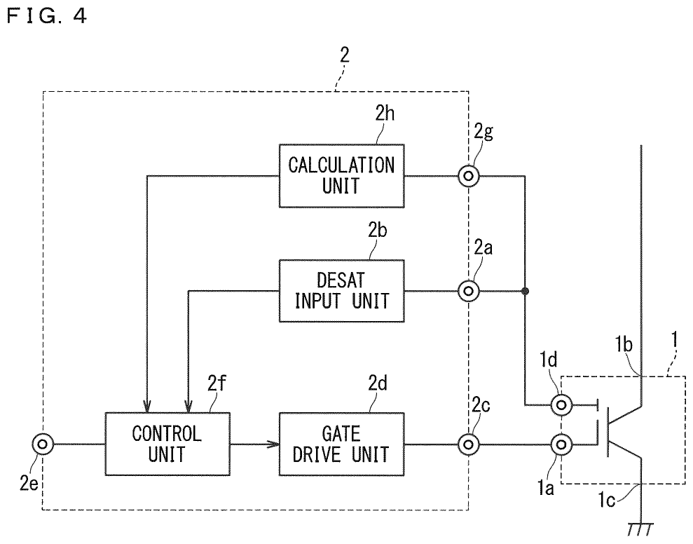

FIG. 4 is a circuit diagram illustrating a configuration of a semiconductor device according to a second preferred embodiment. The semiconductor device of FIG. 4 is similar to a configuration in which an input terminal 2g and a calculation unit 2h are added to the control circuit 2 of FIG. 1. As described below, the control circuit 2 is configured to control the resistor electrically connected to the gate terminal 1a based on a value of a time derivative of the sense voltage at switching of the gate voltage from the first voltage to the second voltage, that is, at switching of the semiconductor switching element 1 from an ON state to an OFF state.

Similarly to the desat terminal 2a, the input terminal 2g is electrically connected to the sense terminal 1d of the semiconductor switching element 1 without interposition of a diode, and the sense voltage output from the sense terminal 1d is input to the input terminal 2g. The calculation unit 2h calculates a value of a time derivative of the sense voltage of the input terminal 2g at switching of the gate voltage from the first voltage to the second voltage.

The gate drive unit 2d includes a plurality of resistor elements (not illustrated) having different resistances, and the plurality of resistor elements are electrically and selectively connectable to the gate terminal 1a of the semiconductor switching element 1. For example, when a value of a time derivative calculated by the calculation unit 2h is equal to or greater than a reference value, the control unit 2f selectively connects the plurality of resistor elements to the gate terminal 1a such that a resistor electrically connected to the gate terminal 1a increases in resistance as the value of the time derivative increases.

According to the semiconductor device of the second preferred embodiment as described above, the gate resistance of the gate terminal 1a can be increased as the value of the time derivative of the sense voltage at switching of the gate voltage from the first voltage to the second voltage increases. When the gate resistance of the gate terminal 1a increases, the switching speed of the semiconductor switching element 1 decreases and the surge voltage decreases. Therefore, when the value of the time derivative of the sense voltage is large, damage to the element due to the excessive surge voltage can be reduced.

In the present disclosure in English, the articles “a” and “an” mean one or more. Thus, “a”, “an”, “one or more”, and “at least one” can be used interchangeably.

Note that each preferred embodiment and each modification can be freely combined, and each embodiment and each modification can be appropriately modified or omitted.

Hereinafter, various aspects of the present disclosure will be collectively described as appendixes.

### Appendix 1

A semiconductor device comprising:
a semiconductor switching element including a gate terminal, a main terminal that is a collector terminal or a drain terminal, and a sense terminal that outputs a sense voltage lower than a voltage of the main terminal; and
a control circuit that includes a desat terminal electrically connected to the sense terminal without interposition of a diode, and controls a gate voltage of the gate terminal based on the sense voltage input to the desat terminal,
wherein, while the semiconductor switching element is short-circuited and the voltage of the main terminal falls and rises, the sense voltage rises without falling.

### Appendix 2

The semiconductor device according to Appendix 1, wherein
the semiconductor switching element is turned on when the gate voltage is a first voltage,
the semiconductor switching element is turned off when the gate voltage is a second voltage, and
the control circuit controls the gate voltage to the second voltage when the gate voltage is the first voltage and the sense voltage is greater than or equal to a predetermined threshold.

### Appendix 3

The semiconductor device according to Appendix 1 or 2, wherein
the semiconductor switching element further includes
a drift layer of a first conductivity type,
a base layer of a second conductivity type provided on an upper side of the drift layer, and
a plurality of trench electrodes provided, via a plurality of insulating films, on a plurality of trenches that reach the drift layer from an upper surface of a semiconductor layer including an upper surface of the base layer, respectively,
and the plurality of trench electrodes include
a gate electrode electrically connected to the gate terminal, and
a floating electrode electrically connected to the sense terminal.

### Appendix 4

The semiconductor device according to Appendix 3, wherein the sense terminal includes a voltage sense pad that outputs, to an outside of the semiconductor switching element, the sense voltage corresponding to a potential of the floating electrode.

### Appendix 5

The semiconductor device according to any one of Appendixes 1 to 4, wherein the semiconductor switching element is a carrier stored trench gate bipolar transistor (CSTBT).

### Appendix 6

The semiconductor device according to any one of Appendixes 1 to 4, wherein the semiconductor switching element is an insulated gate bipolar transistor (IGBT).

### Appendix 7

The semiconductor device according to any one of Appendixes 1 to 4, wherein the semiconductor switching element is a reverse conducting insulated gate bipolar transistor (RC-IGBT).

### Appendix 8

The semiconductor device according to any one of Appendixes 1 to 4, wherein the semiconductor switching element is a metal-oxide-semiconductor field-effect transistor (MOSFET) containing silicon (Si).

### Appendix 9

The semiconductor device according to any one of Appendixes 1 to 4, wherein the semiconductor switching element is a MOSFET containing silicon carbide (SiC).

### Appendix 10

The semiconductor device according to Appendix 1, wherein
the semiconductor switching element is turned on when the gate voltage is a first voltage,
the semiconductor switching element is turned off when the gate voltage is a second voltage, and
the control circuit controls a resistor electrically connected to the gate terminal based on a value of a time derivative of the sense voltage at switching of the gate voltage from the first voltage to the second voltage.

### Appendix 11

The semiconductor device according to any one of Appendixes 1 to 10, wherein
the control circuit includes
a desat input unit that determines whether the sense voltage is greater than or equal to a predetermined threshold,
a gate drive unit that controls the gate voltage, and
a control unit that controls the gate voltage by controlling the gate drive unit based on a determination result of the desat input unit, and
the desat input unit, the gate drive unit, and the control unit are included in an integrated circuit (IC) in one chip.

### Appendix 12

A semiconductor device comprising:
a semiconductor switching element including a gate terminal, a main terminal that is a collector terminal or a drain terminal, and a sense terminal that outputs a sense voltage lower than a voltage of the main terminal; and
a control circuit that includes a desat terminal electrically connected to the sense terminal without interposition of a diode, and controls a gate voltage of the gate terminal based on the sense voltage input to the desat terminal.

While the disclosure has been shown and described in detail, the foregoing description is in all aspects illustrative and not restrictive. It is therefore understood that numerous modifications and variations can be devised.

What is claimed is:

1. A semiconductor device comprising:
a semiconductor switching element including a gate terminal, a main terminal that is a collector terminal or a drain terminal, and a sense terminal that outputs a sense voltage lower than a voltage of the main terminal; and
a control circuit that includes a desat terminal electrically connected to the sense terminal without interposition of a diode, and controls a gate voltage of the gate terminal based on the sense voltage input to the desat terminal,
wherein, while the semiconductor switching element is short-circuited and the voltage of the main terminal falls and rises, the sense voltage rises without falling.

2. The semiconductor device according to claim 1, wherein
the semiconductor switching element is turned on in a case where the gate voltage is a first voltage,
the semiconductor switching element is turned off in a case where the gate voltage is a second voltage, and
the control circuit controls the gate voltage to the second voltage in a case where the gate voltage is the first voltage and the sense voltage is greater than or equal to a predetermined threshold.

3. The semiconductor device according to claim 1, wherein
the semiconductor switching element further includes
a drift layer of a first conductivity type,
a base layer of a second conductivity type provided on an upper side of the drift layer, and
a plurality of trench electrodes provided, via a plurality of insulating films, on a plurality of trenches that reach the drift layer from an upper surface of a semiconductor layer including an upper surface of the base layer, respectively,
and the plurality of trench electrodes include
a gate electrode electrically connected to the gate terminal, and
a floating electrode electrically connected to the sense terminal.

4. The semiconductor device according to claim 3, wherein the sense terminal includes a voltage sense pad that outputs, to an outside of the semiconductor switching element, the sense voltage corresponding to a potential of the floating electrode.

5. The semiconductor device according to claim 1, wherein the semiconductor switching element is a carrier stored trench gate bipolar transistor (CSTBT).

6. The semiconductor device according to claim 1, wherein the semiconductor switching element is an insulated gate bipolar transistor (IGBT).

7. The semiconductor device according to claim 1, wherein the semiconductor switching element is a reverse conducting insulated gate bipolar transistor (RC-IGBT).

8. The semiconductor device according to claim 1, wherein the semiconductor switching element is a metal-oxide-semiconductor field-effect transistor (MOSFET) containing silicon (Si).

9. The semiconductor device according to claim 1, wherein the semiconductor switching element is a MOSFET containing silicon carbide (SiC).

10. The semiconductor device according to claim 1, wherein
the semiconductor switching element is turned on in a case where the gate voltage is a first voltage,
the semiconductor switching element is turned off in a case where the gate voltage is a second voltage, and
the control circuit controls a resistor electrically connected to the gate terminal based on a value of a time derivative of the sense voltage when the gate voltage switches from the first voltage to the second voltage.

11. The semiconductor device according to claim 1, wherein
the control circuit includes
a desat input unit that determines whether the sense voltage is greater than or equal to a predetermined threshold,
a gate drive unit that controls the gate voltage, and
a control unit that controls the gate voltage by controlling the gate drive unit based on a determination result of the desat input unit, and
the desat input unit, the gate drive unit, and the control unit are included in an integrated circuit (IC) in one chip.

12. A semiconductor device comprising:
a semiconductor switching element including a gate terminal, a main terminal that is a collector terminal or a drain terminal, and a sense terminal that outputs a sense voltage lower than a voltage of the main terminal; and
a control circuit that includes a desat terminal electrically connected to the sense terminal without interposition of a diode, and controls a gate voltage of the gate terminal based on the sense voltage input to the desat terminal.
